(19) United States
(12) Patent Application Publication
(10) Pub. No.: US 2009/0147450 A1
(43) Pub. Date: Jun. 11, 2009

(54) Case body and electric apparatus

(76) Inventors: Tomoaki Nara, Saitama (JP); Kenichi Uchiyama, Saitama (JP); Makoto Nakagawa, Saitama (JP); Satoshi Ibuki, Saitama (JP)

Correspondence Address: KRATZ, QUINTOS & HANSON, LLP, 1420 K Street, N.W., Suite 400, WASHINGTON, DC, 20005, US

(21) Appl. No.: 11/887,112

(22) PCT Filed: Mar. 30, 2006
(86) PCT No.: PCT/JP2006/306666

§ 371 Date: Nov. 21, 2008

(30) Foreign Application Priority Data
Mar. 31, 2005 (JP) 2005-102431

(51) Int. Cl. H05K 5/00

(52) U.S. Cl. 361/679.01

(57) ABSTRACT

An attachment section 215A is approximately vertically cut and raised in a tongue-shape on a lateral section 212 of a lower casing 210 provided by press working of a steel plate in a manner that an outer side of the lateral section 212 becomes an upper side of the attachment section 215A on which a circuit board 400 is mounted. A support section 215B is cut and raised on a bottom section 211 of the lower casing 210 so that the lower side of the bottom section 211 becomes opposite to an end surface 213 of the lower casing 210 and a tip end contacts approximately in parallel to a lateral side (in projecting direction) of the attachment section 215A. Attaching force applied when the circuit board 400 is attached to a threaded hole 216 of the attachment section 215A by the screw 410 is received by the support section 215B, so that the axial direction of the screw 410 and the axial direction of the threaded hole 216 are substantially aligned, thereby allowing proper attachment of the circuit board 400.

### TECHNICAL FIELD

The present invention relates to a casing that houses a circuit board for controlling electronic device body and an operation of the electronic device body, and an electronic device.

### BACKGROUND ART

Traditionally, various electronic devices including a personal computer and a processing device for recording and reproducing television (TV) program have been known. Such electronic device has a casing for housing a circuit board that performs various electronic control. The casing houses the circuit board therein, which is screwed on a bend-formed base (see, for instance, Patent Documents 1 to 3).

The structure disclosed in Patent Document 1 is provided with a base support on which a wiring board is attached by an attachment screw on a first side of a heat sink of L-shaped cross section. However, the base support of the Patent Document 1 is bent substantially vertically relative to the first side with a tip end thereof being bent oppositely to a second side and substantially in parallel to the first side to have an L-shaped cross section so as to receive the wiring board thereon. Accordingly, the tip end of the base support is a free end, which is bent on account of pressing force applied when an attachment screw is attached by a tool, so that the attachment screw may not be properly attached to cause attachment failure.

The arrangement shown in Patent Document 2 has a bend-formed base integrated with a bottom side of a lower casing for a circuit board to be attached. The base has a vertical section continuing along the bottom side and a horizontal section bent from the vertical section to show an approximately L-shaped cross section. A hole for screwing the circuit board is provided on the horizontal section. However, the arrangement shown in the Patent Document 2 has the approximately L-shaped cross section integrated with the bottom wall, where a tip end is a free end. Accordingly, as mentioned above, the tip end is bent toward the bottom side by a pressing force applied when an attachment screw is attached by a tool and the like, which may hinder proper screwing and cause attachment failure.

An arrangement shown in Patent Document 3 has a projection on a rear plate of a support having L-shaped cross section, the projection being raised inward and provided with a threaded hole for a board to be screwed. However, the arrangement shown in the Patent Document 3 has the projection bent approximately vertically relative to the rear plate, where a tip end is a free end. Accordingly, as mentioned above, the tip end is bent toward the bottom plate by a pressing force applied when an attachment screw is attached by a tool and the like, which may hinder proper screwing and cause attachment failure.

[Patent Document 1] JP05-167277 A (P.2: right column to P.3: left column, FIG. 3).

[Patent Document 2] JP09-289389 A (P.2: right column to P.4: right column, FIG. 1).

[Patent Document 3] JP2005-33054 A (P.3 to P.4, FIG. 5).

### DISCLOSURE OF THE INVENTION

### Problems to be Solved by the Invention

As discussed above, since the bend-formed portion for the board to be attached is a free end in the traditional arrangements shown in the Patent Documents 1 to 3, the portion deforms on account of the pressing force applied when the board is attached, which may hinder proper attachment of the board.

In view of the above problems and the like, an object of the present invention is to provide a casing and an electronic device that allow proper and secure attachment of a circuit board.

### Means for Solving the Problems

A casing according to an aspect of the present invention is for housing a mounted object, the casing including: a flat bottom section; and a lateral section, a part of at least one of the bottom section and the lateral section being bent toward an inside of the casing to provide an attachment section on which the mounted object is placed and a support section for supporting the attachment section.

An electronic device according to further aspect of the present invention includes: the casing according to the above-mentioned aspect of the present invention; an electronic device body disposed in the inner space in the casing; and a mounted object attached to the mount base of the casing to be disposed in the inner space.

### BRIEF DESCRIPTION OF DRAWINGS

FIG. 1 is a perspective view showing a schematic arrangement of an electronic device according to an embodiment of the present invention.

FIG. 2 is an exploded perspective view of a part of the electronic device according to the embodiment, which is cut out around a mount base.

FIG. 3 is a perspective view showing a part of the casing of the electronic device around the base according to another embodiment of the present invention.

FIG. 4 is a perspective view showing a part of the casing of the electronic device around the mount base according to still another embodiment of the present invention.

FIG. 5 is a perspective view showing a part of the casing of the electronic device around the mount base according to further embodiment of the present invention.

FIG. 6 is a perspective view showing a part of the casing of the electronic device around the mount base according to still further embodiment of the present invention.

FIG. 7 is a perspective view showing a part of the casing of the electronic device around the mount base according to still further embodiment of the present invention.

FIG. 8 is a perspective view showing a part of the casing of the electronic device around the mount base according to still further embodiment of the present invention.

FIG. 9 is a perspective view showing a part of the casing of the electronic device around the mount base according to still further embodiment of the present invention.

FIG. 10 is a perspective view showing a part of the casing of the electronic device around the mount base according to still further embodiment of the present invention.

FIG. 11 is a perspective view showing a part of the casing of the electronic device around the mount base according to still further embodiment of the present invention.

### EXPLANATION OF CODES

100 electronic device

200 casing

201 inner space

211 bottom section

212 lateral section

214 bending line

215 mount base

215A, 215E attachment section

215B, 215C, 215D, 215F, 215G, 215H, 215K support section

216 threaded hole (attachment portion)

300 disk drive (electronic device body)

400 circuit board (mounted object)

410 screw (attachment)

### BEST MODE FOR CARRYING OUT THE INVENTION

Exemplary embodiments of the present invention will be described below with reference to the drawings. In the embodiments, a recording/reproducing device that conducts reproduction and recording of a television-broadcasting program is exemplified. However, the present invention can be applied to any electronic devices such as a personal computer that include an electronic device body operated when charged with electricity, a circuit board mounted thereon with a circuit for controlling the movement of the electronic device body and a casing for housing the circuit board.

### [Structure of Electronic Device]

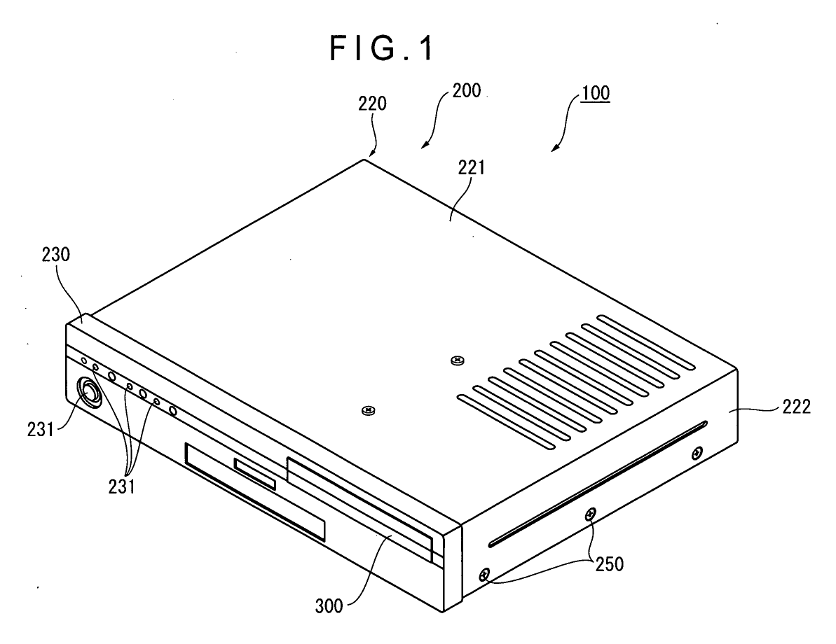

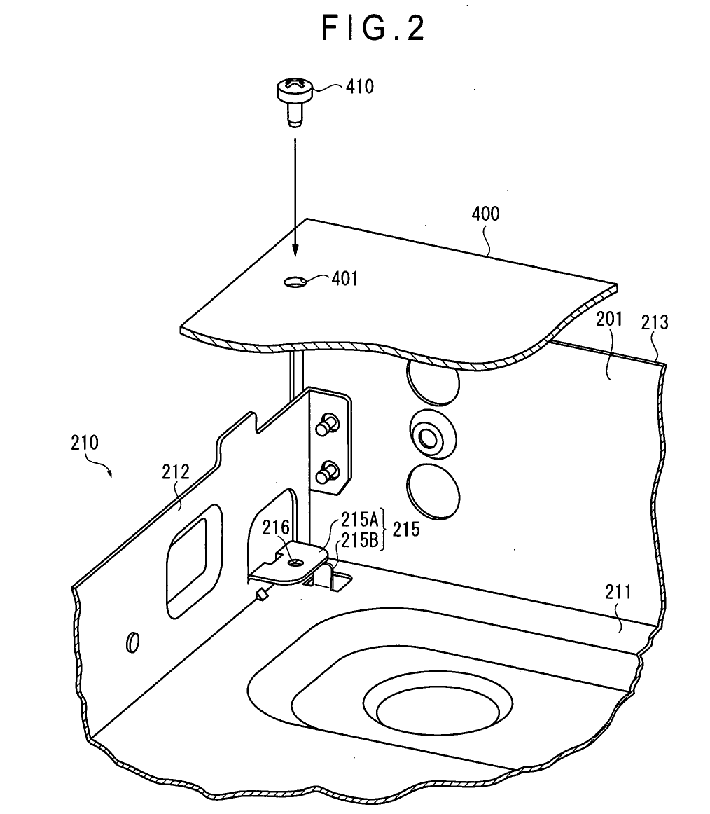

FIG. 1 is a perspective view showing an electronic device according to the present embodiment. FIG. 2 is a perspective view with a part around a mount base being cut out.

In FIG. 1, 100 denotes an electronic device, which conducts a recording processing for acquiring and recording a television-broadcasting program and reproducing processing for reproducing the recorded television-broadcasting program. The electronic device 100 includes: a casing 200; a disk drive 300 (electronic device body) housed within the casing; and a circuit board 400 housed within the casing 200 to control the operation of the disk drive 300 and to control the recording processing and the reproducing processing.

As shown in FIGS. 1 and 2, the casing 200 includes: a lower casing 210 that is open on two sides, i.e. an upper side and a front side; an upper casing 220 that closes the upper side of the lower casing 210 and covers lateral sides of the lower casing 210; and a decorative plate 230 that closes the front side of the lower casing 210 and the upper casing 220. The casing 200 is an approximate rectangle in which an inner space 201 is defined. The lower casing 210 and the upper casing 220 are formed by, for instance, press working of a steel plate (electrical conductive material). The decorative plate 230 is formed of synthetic resin such as acrylonitrile-butadiene-styrene (ABS) and polystyrene (PS) by injection molding and the like.

Various operation buttons 231 are arranged on the front side of the decorative plate 230 in an operable manner. Various signals for setting the operation of the entire electronic device 100 are outputted to the circuit board 400 by an input operation on the operation buttons 231.

As shown in FIG. 2, the lower casing 210 has a flat bottom section 211 disposed on a mount surface so that a lower side of the bottom section 211 opposes to the mount surface such as mount base (not shown) and a floor on which the electronic device 100 is mounted. The lower casing 210 has a pair of lateral sections 212 formed by approximately vertically bending both lateral sides (in front-rear direction) of the bottom section 211 toward upper side (lateral side). The lower casing 210 has an end surface formed by approximately vertically bending a rear side (in front-rear direction) of the bottom section 211 toward the upper side (in the same direction as the lateral sections 212) to provide a substantially box-shaped configuration with the front side and the upper side being opened. Further, a mount base 215 onto which the circuit board 400 is attached is cut and raised on the lower casing 210 by press working. Incidentally, the cut-and-raised by press working may be made in any manner, where a part of a plate is cut along an edge of to-be-cut-and-raised section and subsequently is bent by press working or is directly cut and raised without conducting the cutting process.

The mount base 215 includes an attachment section 215A provided on the lateral section 212 that is cut and raised to be projected in a tongue-shape toward the inner space 201 (inward). The attachment section 215A is approximately vertically cut and raised relative to the lateral section 212 so that a tip end projecting inward relative to the end on the side of the lateral section 212 (base end) is bent from the condition where the tip end is located on upper side of the lateral section 212 relative to the bottom section 211 to be cut and raised toward the bottom section 211, i.e. so that an outer side of the lateral section 212 becomes the upper side on which the circuit board 400 is mounted. A threaded hole 216 for a screw 410 (attachment) to be screwed thereinto (penetrating a screw through hole 401 of the circuit board 400) is provided approximately at the center of the attachment section 215A. The attachment section 215A is bent so that the distance between the upper side of the bottom section 211 and a lower side of the attachment section 215A opposing to the bottom section 211 is larger than the dimension by which the electrical conductive screw 410 for attaching the circuit board 400 projects from the lower side of the attachment section 215A.

The mount base 215 also includes a support section 215B provided on the bottom section 211 that is cut and raised to be projected in a tongue-shape toward the inner space 201 (inward). The support section 215B is cut and raised in a direction orthogonal to cut-and-raise direction of the attachment section 215A so that an end on the side of the bottom section 211 (base end) thereof is located at a position corresponding to a lateral side (in projecting direction) of the attachment section 215A opposing to the end surface 213 to form a plane parallel to-the lateral side. Specifically, the support section 215B is cut and raised so that the tip end of the support section 215B is in contact with a lateral side (in projecting direction) of the attachment section 215A approximately in parallel where the lower side of the bottom section 211 opposes to the end surface 213. As described above, the support section 215B is formed in a tongue-shape projecting by approximately the same dimension as the opposing distance between the attachment section 215A and the bottom section 211. Incidentally, it is preferable that the support section 215B is cut and raised so that at least a part of the tip end of the support section 215B contacting the attachment section 215A is in contact with a remote end of the attachment section 215A relative to the position of the threaded hole 216.

The attachment section 215A and the support section 215B are cut and raised by press-working on the steel-plate lower casing 210 and, subsequently, the lateral sections 212 and the end surface 213 are bend-formed relative to the bottom section 211 by press working. By bend-forming the lateral section 212, the attachment section 215A opposes approximately in parallel to the bottom section 211 and the tip end of the support section 215B contacts the lower side (a side opposing to the bottom section 211) of the attachment section 215A, thereby providing the mount base 215.

As shown in FIG. 1, the upper casing 220 has a flat top plate 221 with approximately the same configuration as the bottom section 211 of the lower casing 210. The upper casing 220 is also provided with a pair of lateral plates formed by bending both lateral sides (in front-rear direction) of the top plate 221 approximately vertically downward to provide an approximately box-shaped configuration with the front side, lower side and the rear side being opened. The upper casing 220 is attached by an attachment 250 such as a screw while the lateral plate is overlaid on an outer surface of the lateral section of the lower casing 210 so that the top plate 221 covers the circuit board 400 and the disk drive 300 that are attached to the lower casing 210 to define the inner space 201.

### [Operation on Electronic Device]

Next, an attachment process for attaching the circuit board 400 will be described as an operation on the electronic device 100 of the above embodiment.

The circuit board 400 is mounted on an upper side of the preformed attachment section 215A of the mount base 215 of the lower casing 210 so that the screw through hole 401 of the circuit board 400 substantially opposes to the threaded hole 216. In this state, the screw 410 is inserted into the screw through hole 401 to be screwed into the threaded hole 216 by an electric power tool and the like. At this time, the attaching force that presses the screw 410 toward the attachment section 215A is applied as a force for pushing the tip end of the attachment section 215A toward the bottom section 211. The attaching force is received by the support section 215B that is in contact with the lower side of the attachment section 215A to prevent the attachment section 215A from being pushed down toward the bottom section 211. Accordingly, the axial direction of the screw 410 (attaching direction of the screw 410) is approximately kept aligned with the axial direction of the threaded hole 216 to allow proper screwing of the screw 410. By the screwing, the circuit board 400 is electrically grounded to the attachment section 215A through the screw 410 screwed into the threaded hole 216.

### [Effect of Electronic Device]

As described above, the mount base 215 on which the circuit board 400 is attached includes: the flat attachment section 215A having the threaded hole 216 for the screw 410 to be attached, the circuit board 400 being mounted on the attachment section 215A by the screw 410; and the support section 215B having a flat side in a direction orthogonal to the flat surface of the attachment section 215A, the support section 215B being interposed between the attachment section 215A and the bottom section 211 to restrict the attachment section 215A from being pushed down toward the bottom section 211, the attachment section 215A and the support section 215B being bend-formed respectively on the lateral section 212 and the bottom section 211 to project toward the inner space 201. Accordingly, even when the attaching force is applied to push down the attachment section 215A in attaching the circuit board 400, the attachment section 215A can be protected from being pushed down and bent by the presence of the support section 215B. Accordingly, the axial direction of the screw 410 to be attached is approximately kept aligned with the axial direction of the threaded hole 216, so that the screw 410 can be securely screwed and proper attachment becomes possible with a simple arrangement. Since the circuit board 400 is securely attached, damage on the circuit board 400 and noise generation caused by shaky movement due to operation of the electronic device 100, vibration from the outside and the like, malfunction on account of short circuit between the circuit board 400 and the other part of the device and the like can be prevented, thus securing stable operation of the device.

The attachment section 215A is cut and raised on the lateral section 212 to be projected toward the inner space 201 and the support section 215B is cut and raised on the bottom section 211 to be projected toward the inner space 201 so that the tip end thereof contacts distal side of the attachment section 215A, thereby providing the mount base 215 for the circuit board 400 to be attached. Accordingly, the circuit board 400 can be securely attached with a simple structure. Further, since the bottom section 211 and the lateral section 212 are respectively cut and raised, in comparison to an arrangement where only one of the bottom section 211 and the lateral section 212 is cut and raised, the opening area formed by cutting and raising is shared by the bottom section 211 and the lateral section 212, so that decrease in the strength of the bottom section 211 and the lateral section 212 can be prevented and the cutting and raising can be easily conducted.

Especially, the support section 215B is cut and raised so that at least a part of the tip end of the support section 215B contacting the attachment section 215A is in contact with the distal end of the attachment section 215A relative to the position of the threaded hole 216. Accordingly, even when a large attaching force is applied on the attachment section 215A, the attaching force is securely received by the support section 215B, thereby preventing the attachment section 215A from being pushed down and bent.

Further, the support section 215B is cut and raised to provide a plane approximately in parallel to the lateral side (in projecting direction) of the attachment section 215A. In other words, the cut-raise direction of the attachment section 215A intersects with the cut-raise direction of the support section 215B. Accordingly, the force during press working is applied on the steel plate as a base of the lower casing 210 in different directions, so that the force is applied on the base in a dispersed manner during press working, thereby preventing position shift during the press working of the base and facilitating the support of the base to allow stable and facilitated press working.

The attachment section 215A is cut and raised so that the tip end thereof is located on a distal side of the lateral section 212 in bend-forming direction. In other words, the attachment section 215A is cut and raised so that the side directed to the outer side of the lateral section 212 becomes the upper side for the circuit board 400 to be mounted. Accordingly, the attachment section 215A can be cut and raised with a relatively large area to allow stable support of the circuit board 400 and the distance from the base end of the attachment section 215A to the threaded hole 216 can be set long, so that attachment process can be conducted even when the screw through hole 401 of the circuit board 400 is located relatively remote from the circumference of the circuit board 400, thereby increasing design option and improving productivity.

The support section 215B is cut and raised so that the tip end thereof is located at the side of the end surface 213 relative to the base end thereof, i.e. so that the lower side of the bottom section 211 opposes to the end surface 213. Accordingly, since there is no opening formed by cutting and raising the support section 215B beneath the attachment section 215A, screwing portion is not exposed from the bottom side of the casing 200, thereby preventing interference against the outside due to the presence of the tip end of the screw 410 at the cut-raised opening.

Since the attachment section 215A having the threaded hole 216 for screwing the circuit board 400 is cut and raised on the lower casing 210 made of electrical conductive material, even when surface treatment is applied on the lower casing 210, electrical grounding can be achieved simultaneously with mechanical attachment of the circuit board 400 by the electrical conductive screw 410 screwed into the threaded hole 216. Further, since a steel plate (electrical conductive material) is used, the mount base can be continuously cut and raised by press working, so that the mount base can be easily provided without impairing productivity. Since the mount base 215 is pressed simultaneously with the press working for providing the lower casing 210, the mount base 215 can be easily provided without complicating the production process.

The casing 200 is constructed by attaching the side plate 222 of the upper casing 220 on the outside of the lateral section 212 of the lower casing 210 on which the attachment section 215A of the mount base 215 is cut and raised. Accordingly, even when the attachment section 215A is cut and raised, the cut-raise opening is covered with the upper casing 220, so that the appearance is prevented from being impaired and leakage of noise and electromagnetic wave generated during the operation of the electronic device such as the disk drive 300 can be prevented.

### [Modifications]

Incidentally, the scope of the present invention is not limited to the above-described embodiment, but includes following modifications as long as an object of the present invention can be achieved.

Though the electronic device of the present invention is exemplified by the electronic device 100 that houses the disk drive 300, the disk drive 300 may not be provided with a tray but may be any disk drive including a so-called slot-in disk drive or a slim drive and disk drive that handles other recording medium such as a hard disk drive or an undetachable recording medium. A drive that processes any recording medium including cylindrical recording medium having a recording surface on an outer circumference thereof and non-disk-shaped recording medium such as a magnetic tape may be used in the present invention. Further, the present invention may be used in any electronic device operated when charged with electricity, such as a communication circuit and an arithmetic device.

The casing body 200 is made of steel plate in the embodiment. However, the casing body 200 may not be made of steel plate, but made of any electrical conductive material including non-ferrous metal such as aluminum alloy or, alternatively, made of synthetic resin plate. Further, the casing body 200 may not be constructed by the lower casing 210, the upper casing 220 and the decorative plate 230. For instance, the inner space may be defined by a cover-shaped upper casing that closes an upper side of a lower casing that opens only the upper side, where a casing body of any shape at least having a bottom section and lateral section may be used. Further, though horizontal arrangement, i.e. a shape having a large bottom section 211 opposing to the mount surface, is used as an example in the embodiment, the present invention may be applied to a vertical arrangement where the side plate 222 opposes to the mount surface.

Though the circuit board 400 is attached by the screw 410 that is screwed to the threaded hole 216 of the mount base 215, any attachment member such as bolt, rivet and eyelet may be used. Any attachment arrangement for attaching any desired attachment member may be used.

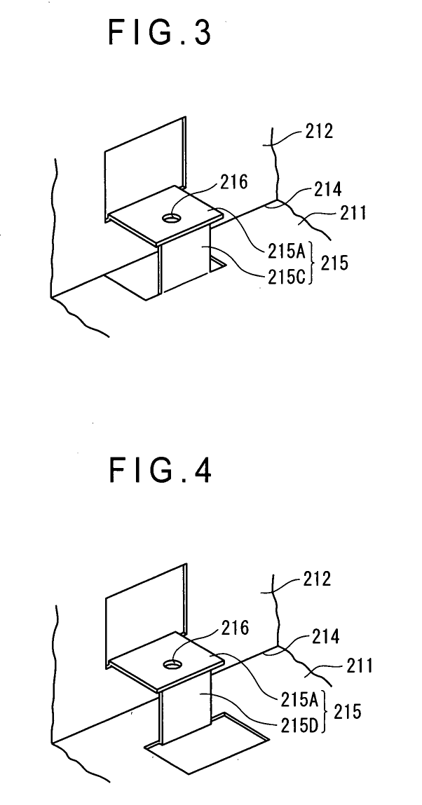

The mount base 215 may not be provided by cutting and raising the lateral section 212 to form the attachment section 215A and cutting and raising the bottom section 211 to form the support section 215B, but may be provided in any manner as long as the attaching force applied on the attachment section 215A is received by the support section 215B located on the force-applied side. Specifically, the arrangements shown in FIGS. 3 to 11 may be used.

The mount base 215 shown in FIG. 3 has an attachment section 215A shown in FIGS. 1 and 2 and a support section 215C cut and raised on the bottom section 211 at a portion opposing to the attachment section 215A. The support section 215C is cut and raised to project toward the inner space 201 while the tip end thereof is located on the side of the bending line 214 between the bottom section 211 and the lateral section 212 relative to the base end thereof, i.e. so that the lower side of the bottom section 211 opposes to the lateral section 212 on which the attachment section 215A is cut and raised. According to the arrangement shown in FIG. 3, the same effect as the embodiment shown in FIGS. 1 and 2, i.e. proper attaching condition of the circuit board 400 with a simple arrangement, can be obtained. Further, since the portion opposing to the attachment section 215A is cut and raised, interference against the other component provided on the bottom section 211 (for instance, a hole for disposing a terminal) is not likely to occur and the mount base 215 can be properly provided within a limited area. Further, since the cut-raise direction of the attachment section 215A is the same as the cut-raise direction of the support section 215C, the force on a steel plate is applied in the same direction during press working, thereby easily achieving excellent press working.

In the mount base shown in FIG. 4, the support section is cut and raised in a reverse direction relative to the support section 215C of the embodiment shown in FIG. 3. Specifically, a support section 215D is cut and raised so that the distal end is located on an opposite side of the bending line 214 relative to the base end thereof. In other words, the support section 215D is cut and raised so that the upper side of the bottom section 211 opposes to the lateral section 212 on which the attachment section 215A is provided. According to the arrangement shown in FIG. 4, the same effect as the embodiments shown in FIGS. 1 and 2 and in FIG. 3 can be provided.

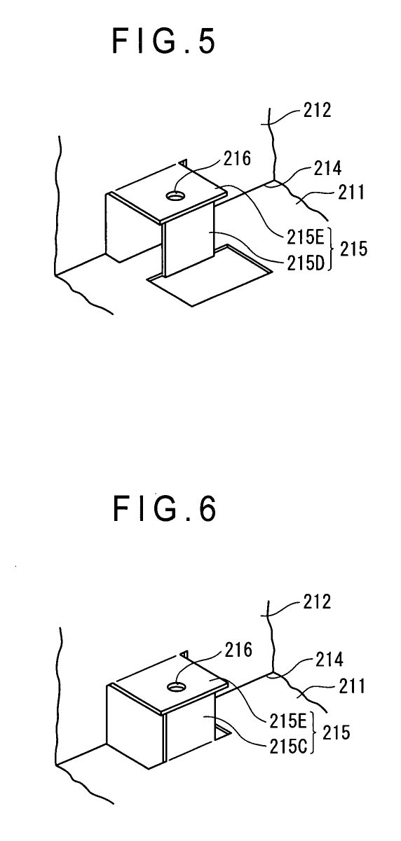

In the mount base shown in FIG. 5, the attachment section is cut and raised in a vertically reverse direction relative to the attachment section 215A of the embodiment shown in FIG. 4. Specifically, the attachment section 215E is cut and raised so that the tip end thereof is located on the side of the bending line 214 between the bottom section 211 and the lateral section 212 relative to the base end thereof, i.e. so that the inner side of the lateral section 212 becomes the upper side of the attachment section 215E. According to the embodiment shown in FIG. 5, the same effect as the above-described embodiments can be attained. Further, since the circuit board 400 does not face the opening provided on the lateral section 212 by the cutting and raising of the attachment section 215E, even when the side plate 222 is not overlaid on the lateral section 212 (i.e. the lateral section 212 is exposed to the outside), short circuit of the circuit board 400 on account of component invading from the lateral side can be prevented, thus providing stable operation.

The mount base 215 shown in FIG. 6 has the attachment face 215E of the embodiment shown in FIG. 5 and the support section 215C of the embodiment shown in FIG. 3. In the embodiment shown in FIG. 6, proper attaching condition of the circuit board 400 can be securely obtained with a simple arrangement as in the above-described embodiments.

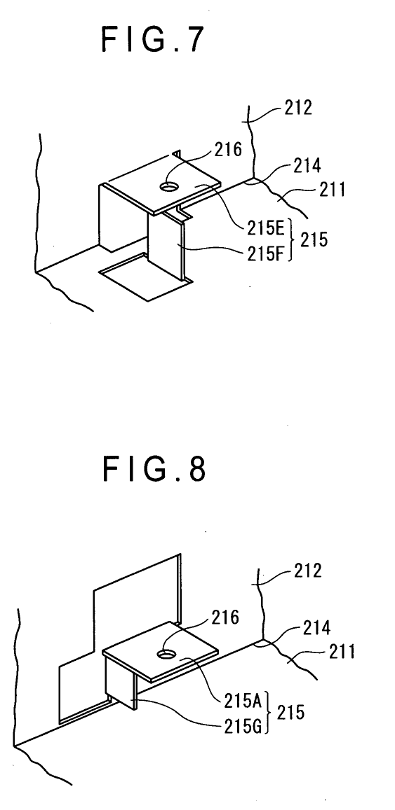

The mount base 215 shown in FIG. 7 uses the same attachment section 215E as the embodiment shown in FIGS. 5 and 6, and the support section 215B shown in FIGS. 1 and 2 is in contact with the attachment section 215A at a lateral side (in projecting direction) opposing to the decorative plate 230. Specifically, the support section 215F is cut and raised so that the tip end thereof is located on the side of the decorative plate 230, i.e. so that the upper side of the bottom surface 211 opposes to the end surface 213 and the tip end contacts a distal side of the attachment section 215E relative to the threaded hole 216. In the embodiment shown in FIG. 7, proper attaching condition of the circuit board 400 can be securely obtained with a simple arrangement as in the above-described embodiments.

Though the attachment sections 215A and 215E are cut and raised on the lateral section 212, and the support sections 215B, 215C, 215D and 215F are cut and raised on the bottom section 211 to provide the mount base 215, the attachment section and the support section may be provided solely on either one of the bottom section 211 and the lateral section 212.

In the mount base 215 shown in FIG. 8, a support section 215G is cut and raised on the lateral section 212 on which the attachment section 215A is cut and raised. Specifically, the support section 215G is cut and raised so that the tip end thereof is located on the side of the decorative plate 230 relative to the base end and the base end is located substantially adjacent to the base end of the attachment section 215A. In other words, the support section 215G is cut and raised toward the inner space 201 in a tongue-shape so that the outer side of the lateral section 212 opposes to the decorative plate 230 and the plane direction becomes approximately orthogonal to the attachment section 215A. An upper end (in projecting direction) of the support section 215G approximately contacts the lower side of the attachment section 215A, i.e. approximately contacts in parallel to a side of the attachment section 215A in projecting direction. In the embodiment shown in FIG. 8, proper attaching condition of the circuit board 400 can be securely obtained with a simple arrangement as in the above-described embodiments. Further, since only the lateral section 212 covered by the upper casing 220 is cut and raised in the arrangement shown in FIG. 8, the attachment portion of the circuit board 400 is not exposed to the outside, so that the appearance is not impaired, malfunction such as short circuit can be securely prevented, and, in addition, leakage of noise and electromagnetic wave can be securely prevented. Further, since the support section 215G is cut and raised so that the side opposing to the bottom section 211 is spaced apart from the bottom section 211 by a predetermined gap, the support section 215G does not touch the bottom section 211 when the lateral side 212 is bent relative to the bottom section 211 by press working, thereby allowing proper bending. Incidentally, the support section 215G may be cut and raised so that the lower end of thereof, i.e. the side opposing to the bottom section 211 touches the bottom section 211 in the arrangement shown in FIG. 8. According to the above arrangement, bending of the attachment section 215A toward the bottom section 211 by the attaching force can be further securely prevented.

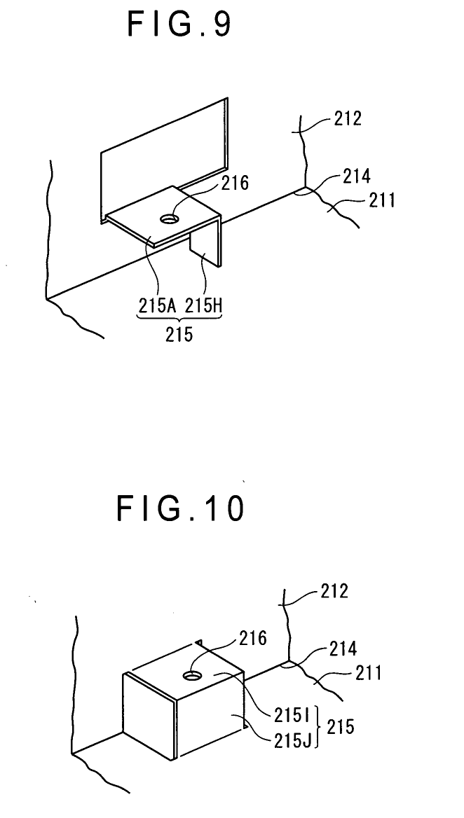

Further, in the mount base 215 shown in FIG. 8, the attachment 215A and the support section 215G may be integrally formed. Specifically, the arrangement shown in FIG. 9 may be employed. The mount base 215 shown in FIG. 9 may be provided by: cutting and raising the lateral section 212 to form the attachment section 215A; bending a lateral side (in projecting direction) of the attachment section 215A toward the bottom section 211; and forming the support section 215H so that the tip end thereof substantially touches the bottom section 211. In this arrangement, proper attaching condition of the circuit board 400 can be securely obtained with a simple arrangement as in the above-described embodiments. Further, since the support section 215H is bend-formed continuously with the attachment section 215A in the arrangement shown in FIG. 9, the attaching force can be sufficiently supported by the support section H with a simple arrangement. Incidentally, though the support section 215H is formed by bending a lateral side (in projecting direction) of the attaching surface 215A, a pair of support sections 215H may be provided on both lateral sides or the tip end (in projecting direction) may be bent toward the bottom section. Incidentally, in the same manner as the arrangement in which a pair of support sections 215H are provided, a plurality of support sections 215B, 215C, 215D, 215F and 215G may be combined as desired to receive the attaching force in the above respective embodiments. By providing a plurality of support sections 215B, 215C, 215C, 215D, 215F, 215G and 215H, further proper attaching condition can be obtained.

In order to integrally provide the attachment section 215A and the support section 215G as in the embodiment shown in FIG. 9, the mount base may be continuously provided by respectively cutting and raising the bottom section 211 and the lateral section 212 as shown in FIG. 10. Specifically, the ridge and valley of the bending line between the bottom section 211 and the lateral section 212 may be reversely arranged, i.e. cut and raised so that the bending line 214A between the continuously provided attachment section 215I and the support section 215J projects toward the inner space 201. In the embodiment shown in FIG. 10, proper attaching condition of the circuit board 400 can be securely obtained with a simple arrangement as in the above-described embodiments. Further, since no free end is formed in the arrangement shown in FIG. 10, further stable attachment condition can be obtained and noise generation caused when the mount base 215 is moved toward and away from the lateral section 212 and the bottom section 211 on account of vibration can be prevented.

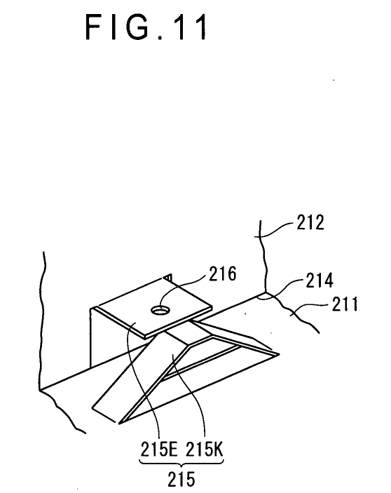

Further, the mount base 215 shown in FIG. 11 has the attachment section 215E of the embodiment shown in FIGS. 5 and 7 and a support section 215K cut and raised to protrude toward the inner space 201 Specifically, the support section 215K has a pair of inclined portions 215K1 that are cut and raised so that base end thereof continues from the bottom section 211 and tip end thereof substantially contacts the lower side of the distal side of the attachment section 215E, and a contact surface 215K2 that continuously bridges the tip end of the inclined portions 215K1 and has an upper side substantially contacts the lower side of the distal side of the attachment section 215E, thereby showing an approximately trapezoidal cross section. In the embodiment shown in FIG. 11, proper attaching condition of the circuit board 400 can be securely obtained with a simple arrangement as in the above-described embodiments. Further, in the arrangement shown in FIG. 11, since the attaching force is shared by the pair of inclined portions 215K1, more secure and stable attachment condition can be provided.

Though the support sections 215B, 215C, 215D, 215F, 215G and 215K are cut and raised to be in contact with the attachment section 215A and 215E, a slight gap may be provided so that elastic deformation toward the bottom section 211 by the attaching force causes the contact with the tip end of the support section 215B.

Alternatively, the support section 215B may substantially contact to the attachment section 215A at a side near the base end relative to the threaded hole 216 instead of the distal side relative to the threaded hole 216.

Specific structure and process for implementing the present invention may be altered as long as an object of the present invention can be achieved.

### Effect of Embodiment

As described above, the mount base 215 on which the circuit board 400 is attached includes: the flat attachment section 215A, 215E having the threaded hole 216 for the screw 410 to be attached, on which the circuit board 400 is mounted by the screw 410; and the support section 215B having a flat side in a direction orthogonal to the flat surface of the attachment section 215A, the support section 215B, 215C, 215D, 215F, 215G, 215H and 215K being interposed between the attachment section 215A, 215E and the bottom section 211 to restrict the attachment section 215A, 215E from being pushed down toward the bottom section 211, the attachment section 215A and the support section 215B being bend-formed on at least one of the bottom section 211 and the lateral section 212 to project toward the inner space 201. Accordingly, even when the attaching force is applied to push down the attachment section 215A, 215E in attaching the circuit board 400, the attachment section 215A, 215E can be protected from being pushed down and bent by the presence of the support section 215B, 215C, 215D, 215F, 215G, 215H and 215K. Accordingly, the axial direction of the screw 410 to be attached is approximately kept aligned with the axial direction of the threaded hole 216, so that the screw 410 can be securely screwed and proper attachment becomes possible with a simple arrangement.

### INDUSTRIAL APPLICABILITY

The present invention can be applied to a casing that houses a circuit board for controlling electronics body and an operation of the electronics body, and electronics.

1-13. (canceled)

14: A casing for housing a mounted object, the casing comprising: a flat bottom section; and
a lateral section,
a part of the bottom section and the lateral section being cut and raised from the lateral section to an inside of the casing to provide an attachment section on which the mounted object is placed,
a part of the bottom section being cut and raised from the bottom section to the inside of the casing to provide a support section for supporting the attachment section.

15: The casing according to claim 14, wherein
a tip end of the attachment section is positioned near a boundary between the bottom section and the lateral section relative to a base end thereof before being cut and raised.

16: The casing according to claim 14, wherein
a base end of the attachment section is positioned near a boundary between the bottom section and the lateral section relative to a tip end thereof before being cut and raised.

17: The casing according to claim 14, wherein
a base end of the support section is positioned near a boundary between the bottom section and the lateral section relative to a tip end thereof before being cut and raised.

18: The casing according to claim 14, wherein
a tip end of the support section is positioned near a boundary between the bottom section and the lateral section relative to a base end thereof before being cut and raised.

19: The casing according to claim 14, wherein
the support section is cut and raised on the bottom section in a direction intersecting a direction in which the attachment section is cut and raised so that the support section becomes approximately parallel to a lateral side (in projecting direction ) of the attachment section.

20: The casing according to claim 14, wherein
the attachment section and the support section are continuously cut and raised so that tip ends of the attachment section and the support section are connected.

21: A casing for housing a mounted object, the casing comprising: a flat bottom section; and
a lateral section, wherein
a part of the lateral section is cut and raised from the lateral section to an inside of the casing to provide an attachment section on which the mounted object is placed, and is bend-formed to extend from a lateral side of the attachment section in projecting direction to the bottom section so that a tip end thereof substantially contacts the bottom section to provide a support section for supporting the attachment section.

22: A casing for housing amounted object, the casing comprising: a flat bottom section; and
a lateral section, wherein
a part of the lateral section is cut and raised from the lateral section to an inside of the casing to provide an attachment section on which the mounted object is placed, and,
a part of the lateral section near the bottom section relative to the attachment section is cut and raised so that a lateral side in projecting direction substantially contact a side of the attachment section opposing to the bottom section to provide a support section for supporting the attachment section.

23: The casing according to claim 14, wherein
the attachment section has an attachment portion for the mounted object to be rigidly attached by an attachment.

24: An electronic device, comprising:
the casing according to claim 14;
an electronic device body disposed in the inner space in the casing; and
a mounted object attached to the mount base of the casing to be disposed in the inner space.
